(19) United States
(12) Patent Application Publication
(10) Pub. No.: US 2026/0190381 A1
(43) Pub. Date: Jul. 2, 2026

(54) HIGH-VOLTAGE NMOSFET AND METHOD FOR MANUFACTURING THE SAME

(71) Applicant: Shanghai Huali Integrated Circuit Corporation, Shanghai (CN)

(72) Inventors: Guopeng CHEN, Shanghai (CN); Zhi TIAN, Shanghai (CN); Qiwei WANG, Shanghai (CN)

(73) Assignee: Shanghai Huali Integrated Circuit Corporation, Shanghai (CN)

(21) Appl. No.: 19/306,402

(22) Filed: Aug. 21, 2025

(30) Foreign Application Priority Data
Jan. 2, 2025 (CN) 202510008323.3

(51) Int. Cl. H10D 30/65; H10D 30/01; H10D 62/10

(52) U.S. Cl. CPC H10D 30/65; H10D 30/0281; H10D 62/116

(57) ABSTRACT

The present application discloses a high-voltage NMOSFET. The P-type well area is formed in the first active area, while the first and second source/drain areas are respectively formed in second and third active areas. The fourth active area is disposed to surround peripheral sides of first to third active areas. The P-type deep diffusion area and a substrate contact area are formed in the fourth active area. The P-type ion implantation area of P-type deep diffusion area is larger than the fourth active area. First and second protrusions of the P-type ion implantation area of the P-type deep diffusion area are provided in areas between the third as well as fourth side surfaces (which lie along the channel width direction) of first active area and corresponding portions of the fourth active area. The present application further discloses a method for manufacturing high-voltage NMOSFET.

### CROSS-REFERENCES TO RELATED APPLICATIONS

This application claims priority to Chinese patent application No. CN202510008323.3, filed on Jan. 2, 2025, the disclosure of which is incorporated herein by reference in its entirety.

### TECHNICAL FIELD

The present application relates to technical field of semiconductor integrated circuit manufacturing, and especially to a high-voltage (HV) NMOSFET. The present application also relates to a method for manufacturing a high-voltage NMOSFET.

### BACKGROUND

In order to economize area as much as possible while improving the double-hump performance of IDVG of HVN MOSFET, HV MOSFET devices are relatively large in size. IDVG represents the curve of drain current (Id) changing with gate voltage (Vg). Therefore, it is expected to find a simple as well as effective method from the perspective of the cause of double hump.

As shown in the FIG. 1, a top view of structure of existing high-voltage NMOSFET is illustrated. The existing high-voltage NMOSFET comprises:

A first active area in a block shape, a second active area as well as a third active area in a strip shape, and a fourth active area in a ring shape are formed in a P-type doped semiconductor substrate surrounded by a field oxide layer 201. In the FIG. 1, the first active area is located in a square frame 101a, the second active area is located in a square frame 101b, the third active area is located in a square frame 101c, and the fourth active area is located between a line 101d and a line 101e.

The first active area has opposite first and second side surfaces and opposite third and fourth side surfaces.

The direction from the first side surface to the second side surface is channel length direction. The direction from the third side surface to the fourth side surface is channel width direction.

The second active area is located outside the first side surface of the first active area, and the third active area is located outside the second side surface of the second active area.

The fourth active area is disposed to surround peripheral sides of the first active area, the second active area, and the third active area.

As shown in FIG. 1, a P-type well area 202 is formed in the first active area, and a gate dielectric layer (not shown) as well as a gate conductive material layer (not shown) are sequentially formed on the top surface of the first active area; the surface of the P-type well area 202 covered by gate conductive material layer is used to form a conductive channel.

A first N-type deep diffusion area (NDF) is formed in the second active area, and a N⁺-doped first source/drain area 203 is formed in surface area of first N-type deep diffusion area.

A second N-type deep diffusion area is formed in third active area, and a N⁺-doped second source/drain area 204 is formed in surface area of the second N-type deep diffusion area.

A P-type deep diffusion area (PDF) is formed in fourth active area, and a P⁺-doped substrate contact area is formed in the surface area of the P-type deep diffusion area.

The P-type impurity used for P-type ion implantation in P-type deep diffusion area comprises boron.

The dopant impurity in the P-type well area 202 comprises boron.

As shown in FIG. 1, the P-type deep diffusion area is formed by the diffusion of the P-type impurities implanted by P-type ions. The P-type ion implantation area of P-type deep diffusion area is larger than the fourth active area and extends into the adjacent field oxide layer 201. P-type ion implantation area of the P-type deep diffusion area is located between line 103a and line 103b.

The first N-type deep diffusion area and the second N-type deep diffusion area are both formed by diffusion of the N-type impurities implanted by N-type ions. The N-type ion implantation area of the first N-type deep diffusion area is larger than the second active area and extends into the adjacent field oxide layer 201 as well as the first active area. As shown in FIG. 1, the N-type ion implantation area of the first N-type deep diffusion area is located within box 102a.

The N-type ion implantation area of the second N-type deep diffusion area is larger than third active area and extends into the adjacent field oxide layer 201 and the first active area. As shown in FIG. 1, N-type ion implantation area of the second N-type deep diffusion area is located within box 102b.

There are two causes of double hump:

On the one hand, the channel concentration is reduced due to boron (B) segregation at the corners of the active area (AA).

As shown in FIG. 2, an enlarged view of the main area of FIG. 1 is illustrated. FIG. 2 only shows internal area of the fourth active area shown in FIG. 1. It can be seen that, as shown by arrow line 104, a quantity of P-type impurities such as boron in first active area segregates from the third and fourth side surfaces of the first active area into the field oxide layer 201, so that the P-type doping concentration in the top corner area of the third and the fourth side surfaces of the first active area as shown in the dashed box 105 will be reduced, which will reduce the threshold voltage of the top corner area of the third and the fourth side surfaces of first active area. Since gate voltage exceeds corresponding threshold voltage, the conduction channel at the bottom is turned on, and therefore, conduction current in the corner areas at third and fourth side surfaces of the first active area is turned on first; and the P-type doping concentration in the internal body area of the first active area between the third and the fourth side surfaces of the first active area is maintained, threshold voltage of the internal body area of the first active area is also maintained. Therefore, only when the gate voltage is further increased to be greater than the threshold voltage of the internal body area of the first active area, the conduction channel in internal body area of the first active area will be turned on. This phenomenon of the edge turning on first and the middle area turning on later forms a double-hump phenomenon in the IDVG curve.

Curve 601 in FIG. 6 is an IDVG curve of existing high-voltage NMOSFET. It can be seen that current hump, which appears at a relatively low gate voltage (Vg) as indicated by circle 603, is generated due to conduction current turning on in corner areas at the third and fourth side surfaces of the first active area. Subsequently, after the conduction channel in the internal body area of the first active area is turned on, a current hump is further formed. The current hump shown in the circle 603 will produce subthreshold leakage, so it is necessary to overcome this leakage.

On the other hand, due to the presence of sharp corners at AA corners, gate electric field is stronger in these areas, which leads to earlier turn-on of the conduction channel at the AA corners. In existing methods, improvements to the sharp corners at the AA corners can be made from both perspectives of layout and process. From the process perspective, continuous implementation of corner implantation process (CIP) can be used to reduce the sharpness of the corners. From the layout perspective, modifications to AA pattern can be made. However, both approaches tend to be relatively costly and time-consuming.

### BRIEF SUMMARY

According to some embodiments in this application, a high-voltage NMOSFET disclosed in this application comprising: a first active area having block shape, a second active area and a third active area each having strip shape and a fourth active area having annular shape, all formed in P-type doped semiconductor substrate and surrounded by field oxide layer, wherein
the first active area has opposite first side surface and second side surface as well as opposite third side surface and fourth side surface, wherein
the direction from the first side surface to the second side surface corresponds to the channel length direction, and direction from the third side surface to the fourth side surface corresponds to channel width direction, wherein
the second active area is located outside first side surface of the first active area, and the third active area is located outside second side surface of the second active area, wherein
the fourth active area is disposed to surround the peripheral sides of the first, second, and third active areas, wherein
a P-type well area is formed in the first active area, and a gate dielectric layer as well as gate conductive material layer are sequentially formed on the top surface of the first active area, wherein surface of P-type well area covered by the gate conductive material layer is configured to form a conduction channel;
a first N-type deep diffusion area is formed in second active area, and an N⁺-doped first source/drain area is formed in surface area of first N-type deep diffusion area;
a second N-type deep diffusion area is formed in third active area, and a N⁺-doped second source/drain area is formed in surface area of the second N-type deep diffusion area;
a P-type deep diffusion area is formed in the fourth active area, and a P⁺-doped substrate contact area is formed in surface area of P-type deep diffusion area, wherein

P-type deep diffusion area is formed by diffusion of P-type impurities introduced through P-type ion implantation, wherein a P-type ion implantation area of the P-type deep diffusion area is larger than the fourth active area and extends into an adjacent field oxide layer, wherein the P-type ion implantation area comprises a first protruding portion located in an area between a third side surface of the first active area and a corresponding portion of the fourth active area, wherein the P-type ion implantation area comprises a second protruding portion located in the area between the fourth side surface of the first active area and the corresponding portion of the fourth active area, wherein

P-type impurities implanted by P-type ion implantation in the P-type deep diffusion area at the first protruding portion and the second protruding portion are incorporated into the field oxide layer to reduce segregation of P-type impurities from the third and fourth side surfaces of first active area into the field oxide layer, thereby increasing threshold voltage of the corner areas at the third and fourth side surfaces of the first active area.

In some cases, the first N-type deep diffusion area and the second N-type deep diffusion area are both formed by the diffusion of N-type impurities introduced through N-type ion implantation, wherein
an N-type ion implantation area of the first N-type deep diffusion area is larger than the second active area and extends into an adjacent field oxide layer and into the first active area, and wherein
an N-type ion implantation area of second N-type deep diffusion area is larger than the third active area and extends into an adjacent field oxide layer and into first active area.

In some cases, a minimum distance between first protruding portion and an adjacent N-type ion implantation area of the first N-type deep diffusion area is greater than or equal to a distance between an inner edge of a P-type ion implantation area of the P-type deep diffusion area (outside the first as well as second protruding portions) and an adjacent edge of the N-type ion implantation area of the first N-type deep diffusion area, and wherein
a minimum distance between the second protruding portion and an adjacent N-type ion implantation area of the second N-type deep diffusion area is greater than or equal to a distance between an inner edge of P-type ion implantation area of P-type deep diffusion area (outside the first and second protruding portions) and an adjacent edge of the N-type ion implantation area of the second N-type deep diffusion area.

In some cases, the bottom surfaces of the first N-type deep diffusion area, the second N-type deep diffusion area and the P-type deep diffusion area extend below a bottom surface of the field oxide layer.

In some cases, the P-type impurities introduced by the P-type ion implantation into the P-type deep diffusion area comprise boron, and wherein

the dopant impurities in the P-type well area comprise boron.

In some cases, high-voltage P-well is formed in surface area of the semiconductor substrate, and the first active area, the second active area, the third active area as well as the fourth active area are all formed within the high-voltage P-well.

In some cases, the P-type well area is formed from the high-voltage P-well.

In some cases, semiconductor substrate comprises a silicon substrate.

According to some embodiments in this application, a method for manufacturing a high-voltage NMOSFET is disclosed in the following steps:

Step 1: forming a field oxide layer in a P-type doped semiconductor substrate and forming a first active area in a block shape, a second active area and a third active area in a strip shape, and a fourth active area in an annular shape surrounded by the field oxide layer, wherein
the first active area has opposite first and second side surfaces and opposite third and fourth side surfaces, wherein
direction from the first side surface to the second side surface represents a channel length direction, and direction from the third side surface to the fourth side surface represents a channel width direction, wherein
the second active area is located outside first side surface of the first active area, the third active area is located outside second side surface of the second active area, and
the fourth active area is disposed to surround the peripheral sides of the first active region, the second active region, and the third active region;

Step 2: forming a P-type well area in the first active area;

Step 3: performing the N-type ion implantation and diffusing the implanted N-type impurities to form a first N-type deep diffusion area in the second active area as well as a second N-type deep diffusion area in the third active area;

Step 4: performing the P-type ion implantation and diffusing the implanted P-type impurities to form a P-type deep diffusion area in the fourth active area, wherein
the P-type ion implantation area of the P-type deep diffusion area is larger than the fourth active area and extends into the adjacent field oxide layer, wherein the P-type ion implantation area comprises a first protruding portion located in area between the third side surface of the first active area and a corresponding portion of the fourth active area, and a second protruding portion is located in area between the fourth side surface of the first active area and a corresponding portion of the fourth active area, wherein
at the first and second protruding portions, P-type impurities introduced by P-type ion implantation are incorporated into the field oxide layer to reduce segregation of P-type impurities from the third and fourth side surfaces of the first active area into the field oxide layer, thereby increasing threshold voltage in corner areas at the third and fourth side surfaces of the first active area;

Step 5: forming gate dielectric layer and gate conductive material layer sequentially on top surface of the first active area, wherein surface of the P-type well area covered by the gate conductive material layer is configured to form a conduction channel;

Step 6: performing N⁺ ion implantation to form the first source/drain area in surface area of the first N-type deep diffusion area and the second source/drain area in surface area of the second N-type deep diffusion area; and

Step 7: performing P⁺ ion implantation to form the substrate contact area in surface area of the P-type deep diffusion area.

In some cases, the N-type ion implantation area of first N-type deep diffusion area is larger than the second active area and extends into adjacent field oxide layer and into the first active area, and wherein
an N-type ion implantation area of second N-type deep diffusion area is larger than the third active area and extends into adjacent field oxide layer and into the first active area.

In some cases, a minimum distance between first protruding portion as well as the adjacent N-type ion implantation area of the first N-type deep diffusion area is greater than or equal to a distance between an inner edge of a P-type ion implantation area of the P-type deep diffusion area (outside the first as well as second protruding portions) and adjacent edge of N-type ion implantation area of the first N-type deep diffusion area, and wherein
a minimum distance between the second protruding portion and adjacent N-type ion implantation area of the second N-type deep diffusion area is greater than or equal to the distance between an inner edge of P-type ion implantation area of the P-type deep diffusion area (outside the first and second protruding portions) and adjacent edge of the N-type ion implantation area of the second N-type deep diffusion area.

In some cases, the bottom surface of the first N-type deep diffusion area, the second N-type deep diffusion area as well as the P-type deep diffusion area extend below bottom surface of the field oxide layer.

In some cases, the P-type impurities introduced by the P-type ion implantation into the P-type deep diffusion area comprise boron, and wherein
the dopant impurities in the P-type well area comprise boron.

In some cases, a high-voltage P-well is formed in a surface area of semiconductor substrate, and the first active area, the second active area, the third active area and the fourth active area are all formed within the high-voltage P-well.

In some cases, step 2 is omitted and the P-type well area is formed from the high-voltage P-well.

In some cases, semiconductor substrate comprises silicon substrate.

The present application provides specially configured P-type ion implantation area for P-type deep diffusion area that is disposed to surround peripheral sides of the high-voltage NMOSFET and serves to draw out semiconductor substrate. Specifically, a first protruding portion as well as a second protruding portion of the P-type ion implantation area are formed in the areas between the third and fourth side surfaces (located on both sides of the first active area along channel width direction) as well as corresponding fourth active area. The first and second protruding portions enable incorporation of P-type impurities into the field oxide layer outside third and fourth side surfaces of the first active area, thereby reducing the segregation of P-type impurities from the first active area into the field oxide layer at the third and fourth side surfaces. The P-type doping concentration in corner areas at third as well as fourth side surfaces of the first active area is maintained, which increases the threshold voltage of these corner areas. As a result, threshold voltage across the entire first active area remains uniform, preventing the premature turn-on caused by threshold voltage reduction at corner areas. This effectively improves double-hump phenomenon in IDVG curve and reduces the subthreshold leakage of the device.

The first protruding portion as well as the second protruding portion of the present application can be implemented merely by modifying the layout of the P-type ion implantation area of the P-type deep diffusion area without requiring the additional photolithography steps. Therefore, the present application also offers the advantages of low technical implementation complexity and reduced manufacturing cost.

### BRIEF DESCRIPTION OF THE DRAWINGS

The present application is further described in detail below with the reference to the accompanying drawings and specific embodiments:

FIG. 1 is a top view of a existing high-voltage NMOSFET;

FIG. 2 is an enlarged view of the body area of FIG. 1;

FIG. 3 is a top view of the structure of a high-voltage NMOSFET according to an embodiment of the present application;

FIG. 4 is a cross-sectional view taken along the dashed line AA in FIG. 3;

FIG. 5 is an enlarged view of the body area in FIG. 3;

FIG. 6 is a comparison diagram of IDVG curves between high-voltage NMOSFET of the embodiment of the present application and the existing high-voltage NMOSFET.

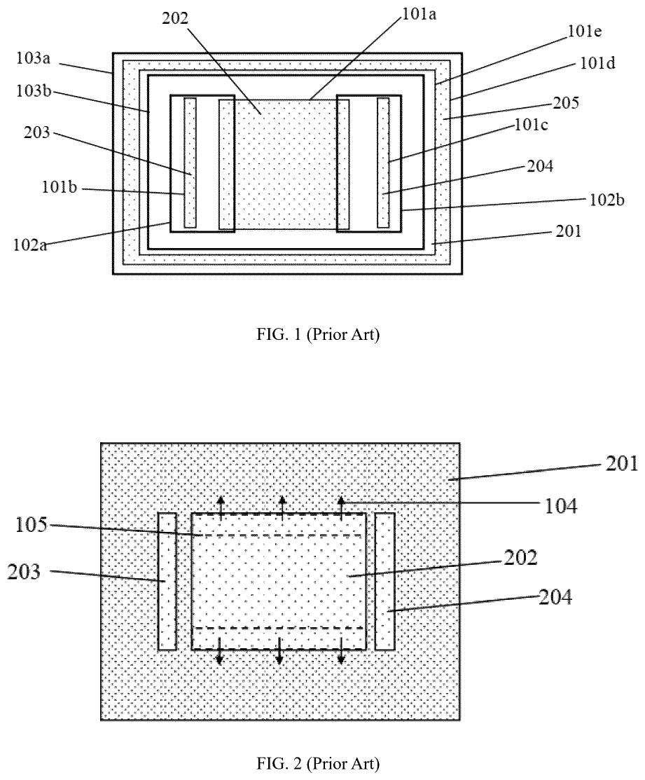

### DETAILED DESCRIPTION OF THE DISCLOSURE

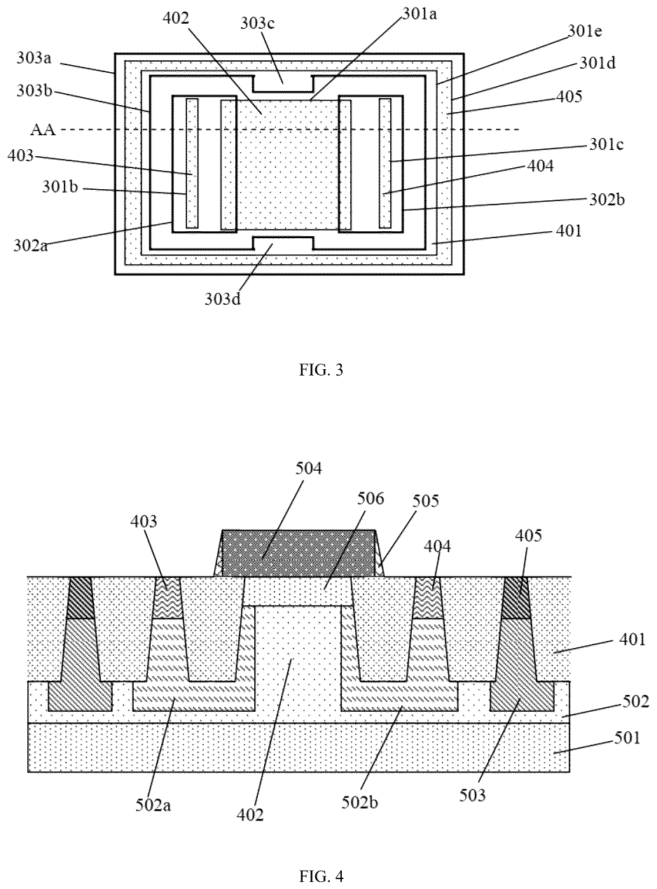

As shown in FIG. 3, it is a top view of the high-voltage NMOSFET according to an embodiment of the present application. FIG. 4 is a cross-sectional view along the dashed line AA of FIG. 3. The high-voltage NMOSFET according to embodiment of present application comprises:

The block-shaped first active area, the strip-shaped second active area as well as the third active area and the annular fourth active area are formed in the P-type doped semiconductor substrate 501 surrounded by field oxide layer 401. In FIG. 3, the first active area is located within box 301a, the second active area is located within box 301b, the third active area is located within box 301c, and the fourth active area is located between line 301d and line 301e.

In the embodiment of the present application, as shown in FIG. 4, high-voltage P-well 502 is formed in surface area of the semiconductor substrate 501, and the first active area, the second active area, the third active area and the fourth active area are all formed in the high-voltage P-well 502.

The semiconductor substrate 501 comprises silicon substrate.

The field oxide layer 401 adopts shallow trench isolation (STI).

The first active area has opposite first and second side surfaces as well as opposite third and fourth side surfaces.

The direction from the first side surface to the second side surface is channel length direction, and direction from the third side surface to the fourth side surface is channel width direction.

The second active area is located outside the first side surface of the first active area, and the third active area is located outside second side surface of the second active area.

The fourth active area surrounds periphery of the first active area, the second active area, and the third active area.

As shown in FIG. 4, P-type well area 402 is formed in the first active area, and gate dielectric layer 506 as well as gate conductive material layer 504 are sequentially formed on the top surface of the first active area; the surface of the P-type well area 402 covered by the gate conductive material layer 504 is used to form conductive channel. The sidewall 505 is also formed on the side of the gate conductive material layer 504.

In some embodiments, the P-type well area 402 is constituted by the high-voltage P-well 502. In other embodiments, P-type well area 402 is formed by further P-type well doping based on the high-voltage P-well 502.

The first N-type deep diffusion area 502a is formed in the second active area, and N⁺-doped first source/drain area 403 is formed in the surface area of the first N-type deep diffusion area 502a.

The second N-type deep diffusion area 502b is formed in the third active area, and N⁺-doped second source/drain area 404 is formed in the surface area of the second N-type deep diffusion area 502b.

The P-type deep diffusion area 503 is formed in the fourth active area, and the P⁺-doped substrate contact area 405 is formed in surface area of the P-type deep diffusion area 503.

In some embodiments, the P-type impurity used for P-type ion implantation in the P-type deep diffusion area 503 comprises boron.

The dopant impurity used in the P-type well area 402 also comprises boron.

As shown in FIG. 3, the P-type deep diffusion area 503 is formed by diffusion of P-type impurities implanted via P-type ion implantation. The P-type ion implantation area of the P-type deep diffusion area 503 is larger than the fourth active area and extends into adjacent field oxide layer 401. The P-type ion implantation area of P-type deep diffusion area 503 is located between line 303a and line 303b. The first protruding portion 303c of P-type ion implantation area of the P-type deep diffusion area 503 is located in the area between the third side surface of the first active area and the corresponding portion of the fourth active area. In the area between the fourth side surface of the first active area and the corresponding portion of the fourth active area, the ion implantation area of the P-type deep diffusion area 503 includes the second protruding portion 303d.

At the first protruding portion 303c as well as the second protruding portion 303d, P-type dopants implanted in the P-type deep diffusion area 503 are incorporated into field oxide layer 401, thereby reducing the segregation of P-type dopants from the third and fourth sides of the first active area into the field oxide layer 401, and thus increasing the threshold voltage at the corner areas of the third and fourth side surfaces of the first active area.

The first N-type deep diffusion area 502a and the second N-type deep diffusion area 502b are both formed by diffusion of N-type impurities implanted by N-type ions. The N-type ion implantation area of the first N-type deep diffusion area 502a is larger than second active area and extends into the adjacent field oxide layer 401 and the first active area. As shown in FIG. 3, the N-type ion implantation area of first N-type deep diffusion area 502a is located in the box 302a.

The N-type ion implantation area of second N-type deep diffusion area 502b is larger than the third active area and extends into the adjacent field oxide layer 401 and the first active area. As shown in FIG. 3, the N-type ion implantation area of second N-type deep diffusion area 502b is located in the box 302b.

In the embodiment of the present application, the minimum distance between the first protruding portion 303c and the adjacent N-type ion implantation area of first N-type deep diffusion area 502a is greater than or equal to the distance between the inner edge of the P-type ion implantation area of P-type deep diffusion area 503 outside the first protruding portion 303c as well as the second protruding portion 303d and the edge of the N-type ion implantation area of the adjacent first N-type deep diffusion area 502a, so that device breakdown voltage can be maintained. In other embodiments, the minimum distance between the first protruding portion 303c and the adjacent N-type ion implantation area of the first N-type deep diffusion area 502a is less than the distance between inner edge of the P-type ion implantation area of P-type deep diffusion area 503 outside first protruding portion 303c as well as the second protruding portion 303d and the edge of the N-type ion implantation area of the adjacent first N-type deep diffusion area 502a.

The minimum distance between the second protruding portion 303d and the adjacent N-type ion implantation area of second N-type deep diffusion area 502b is greater than or equal to the distance between the first protruding portion 303c and inner edge of the P-type ion implantation area of the P-type deep diffusion area 503 outside the second protruding portion 303d and the edge of N-type ion implantation area of the adjacent second N-type deep diffusion area 502b. In other embodiments, the minimum distance between the second protruding portion 303d and the adjacent N-type ion implantation area of the second N-type deep diffusion area 502b is less than the distance between the first protruding portion 303c and the inner edge of the P-type ion implantation area of the P-type deep diffusion area 503 outside the second protruding portion 303d and the edge of the N-type ion implantation area of the adjacent second N-type deep diffusion area 502b.

Bottom surfaces of the first N-type deep diffusion area 502a, the second N-type deep diffusion area 502b as well as the P-type deep diffusion area 503 all extend below the bottom surface of the field oxide layer 401.

The embodiment of the present application makes special arrangement for P-type ion implantation area surrounding the high-voltage NMOSFET and used to lead out the P-type deep diffusion area 503 of semiconductor substrate 501. The first protruding portion 303c and the second protruding portion 303d of the P-type ion implantation area are arranged on the side surfaces of the first active area in the channel width direction, i.e., outside the third side surface and the fourth side surface and between the corresponding fourth active area. The first protruding portion 303c and the second protruding portion 303d enable incorporation of P-type impurities into the field oxide layer 401 located outside the third and fourth side surfaces of the first active area, thereby reducing the segregation of P-type impurities from the third and fourth side surfaces of the first active area into the field oxide layer 401, and the P-type doping concentration in the corner areas at the third side surface and the fourth side surface of the first active area can be maintained, thereby increasing threshold voltage of the corner areas at the third side surface and the fourth side surface of first active area, so that the threshold voltage pairs of each area of the first active area are maintained, and the threshold voltage of the corner areas at the third side surface and the fourth side surface of the first active area is prevented from being reduced and prematurely turned on, thereby improving the double-hump phenomenon of the ID-VG curve of the device and reducing the subthreshold leakage of the device.

The first protruding portion 303c as well as the second protruding portion 303d of the embodiment of present application only need to change layout of P-type ion implantation area of P-type deep diffusion area 503, and no additional photolithography layers need to be added. Therefore, the embodiment of the present application also has the advantages of low technical implementation difficulty and low process cost.

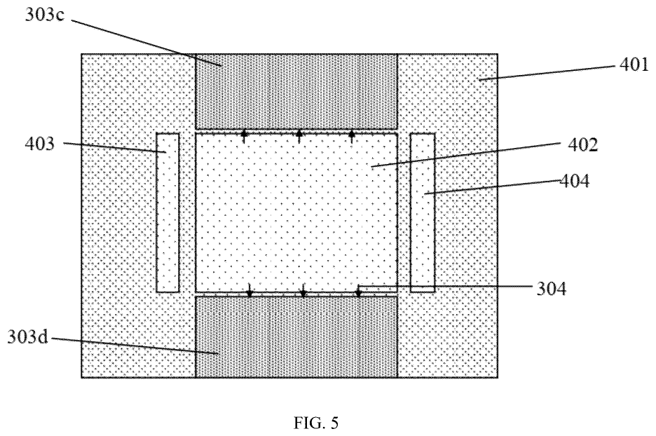

As shown in FIG. 5, which is an enlarged view of the main area in FIG. 3, only internal area of the fourth active area illustrated in FIG. 3 is displayed. It can be seen that the first protruding portion 303c and the second protruding portion 303d are located within field oxide layer 401. The P-type impurities, such as boron, implanted in the first protruding portion 303c and the second protruding portion 303d diffuse and extend across a majority of width of the corresponding field oxide layer 401. As a result, the number of P-type impurities segregating from the third as well as fourth side surfaces of the first active area into field oxide layer 401, as indicated by arrow 304, is significantly reduced. This ensures that P-type doping concentration at the corner areas of the third as well as fourth side surfaces of first active area is maintained, thereby preventing decrease i n threshold voltage. Consequently, premature turn-on of the conductive channels at the corner areas of the third and fourth side surfaces of first active area is avoided, thereby eliminating the double-hump phenomenon in the ID-VG characteristic curve.

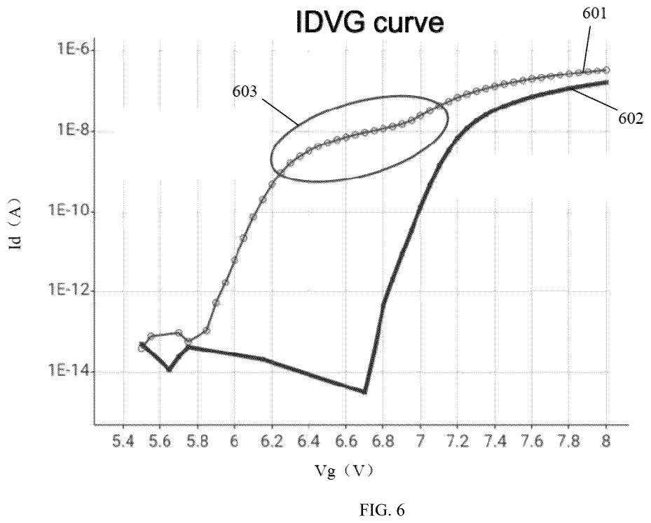

As shown in FIG. 6, it is a comparison diagram of ID-VG curves of high-voltage NMOSFET of the embodiment of present application and the existing high-voltage NMOSFET. Curve 602 is the ID-VG curve of the high-voltage NMOSFET of the embodiment of present application, the horizontal axis is the gate voltage (Vg), and the vertical axis is drain electrode (Vd); Curve 601 is the ID-VG curve of the existing high-voltage NMOSFET. It can be seen that the current hump generated when the turn-on occurs at a lower Vg as shown in the circle 603 in curve 601 is avoided in curve 602.

Referring to the top view of FIG. 3 as well as the cross-sectional view of FIG. 4, the method for manufacturing the high-voltage NMOSFET according to the embodiment of the present application includes the following steps:

Step 1: The field oxide layer 401 is formed in P-type doped semiconductor substrate 501. The field oxide layer 401 encloses and defines a block-shaped first active area, a strip-shaped second active area, a strip-shaped third active area and an annular fourth active area. As shown in FIG. 3, first active area is located within box 301a, the second active area is located within box 301b, the third active area is located within box 301c, and the fourth active area is located between line 301d and line 301e.

In the embodiment of the present application, as shown in FIG. 4, high-voltage P-well 502 is formed in the surface area of the semiconductor substrate 501, and the first active area, the second active area, the third active area and the fourth active area are all formed in the high-voltage P-well 502.

The semiconductor substrate 501 comprises silicon substrate.

The field oxide layer 401 is isolated by shallow trench.

The first active area has opposite first as well as second side surfaces and opposite third as well as fourth side surfaces.

The direction from the first side surface to the second side surface is channel length direction, and the direction from the third side surface to the fourth side surface is channel width direction.

The second active area is located outside the first side surface of the first active area, and the third active area is located outside the second side surface of the second active area.

The fourth active area surrounds periphery of the first active area, the second active area, and the third active area.

Step 2: The P-type well area 402 is formed in the first active area.

In some embodiments, the P-type well area 402 is formed by high-voltage P-well 502, in which Step 2 may be omitted. In some other embodiments, the P-type well area 402 is formed by further P-type well doping based on the high-voltage P-well 502.

The doping impurities of the P-type well area 402 include boron.

Step 3: N-type ion implantation is performed, and the implanted N-type dopants are diffused. As a result, the first N-type deep diffusion area 502a is formed in second active area, and the second N-type deep diffusion area 502b is formed in the third active area.

The N-type ion implantation area of the first N-type deep diffusion area 502a is larger than the second active area and extends into the adjacent field oxide layer 401 and the first active area. As shown in FIG. 3, N-type ion implantation area of the first N-type deep diffusion area 502a is located within the box 302a.

The N-type ion implantation area of second N-type deep diffusion area 502b is larger than the third active area and extends into the adjacent field oxide layer 401 and the first active area. As shown in FIG. 3, the N-type ion implantation area of second N-type deep diffusion area 502b is located within the box 302b.

Step 4: P-type ion implantation is performed, and implanted P-type impurities are diffused to form a P-type deep diffusion area 503 in the fourth active area.

The P-type ion implantation area of the P-type deep diffusion area 503 is larger than the fourth active area and extends into the adjacent field oxide layer 401. In the area between the third side surface of the first active area and the corresponding fourth active area, the P-type ion implantation area of the P-type deep diffusion area 503 includes first protruding portion 303c. In the area between the fourth side surface of the first active area and the corresponding fourth active area, the P-type ion implantation area of the P-type deep diffusion area 503 includes a second protruding portion 303d.

At the first protruding portion 303c and the second protruding portion 303d, P-type impurities of the P-type deep diffusion area 503 are implanted into the field oxide layer 401. This reduces the segregation of P-type impurities from the third and fourth side surfaces of the first active area into the field oxide layer 401, thereby increasing the threshold voltage at the corner areas of the third and fourth side surfaces of the first active area.

In some embodiments, P-type impurities implanted by the P-type ions in the P-type deep diffusion area 503 comprise boron.

In the embodiment of the present application, the minimum distance between the first protruding portion 303c and the adjacent N-type ion implantation area of first N-type deep diffusion area 502a is greater than or equal to the distance between inner edge of the P-type ion implantation area of the P-type deep diffusion area 503 outside the first protruding portion 303c and the second protruding portion 303d and the edge of N-type ion implantation area of the adjacent first N-type deep diffusion area 502a, so that the device breakdown voltage can be maintained. In other embodiments, minimum distance between first protruding portion 303c and adjacent N-type ion implantation area of the first N-type deep diffusion area 502a is less than the distance between the inner edge of the P-type ion implantation area of the P-type deep diffusion area 503 outside the first protruding portion 303c and the second protruding portion 303d and the edge of the N-type ion implantation area of the adjacent first N-type deep diffusion area 502a.

The minimum distance between second protruding portion 303d as well as adjacent N-type ion implantation area of the second N-type deep diffusion area 502b is greater than or equal to the distance between the inner edge of the P-type ion implantation area of the P-type deep diffusion area 503 outside the first protruding portion 303c and the second protruding portion 303d, and edge of adjacent N-type ion implantation area of the second N-type deep diffusion area 502b. In other embodiments, the minimum distance between the second protruding portion 303d and the adjacent N-type ion implantation area of second N-type deep diffusion area 502b may be less than the distance between the inner edge of the P-type ion implantation area of the P-type deep diffusion area 503 outside the first protruding portion 303c and the second protruding portion 303d, and the edge of the adjacent N-type ion implantation area of the second N-type deep diffusion area 502b.

Bottom surfaces of the first N-type deep diffusion area 502a, the second N-type deep diffusion area 502b as well as the P-type deep diffusion area 503 all extend below the bottom surface of the field oxide layer 401.

Step 5: On the top surface of the first active area, the gate dielectric layer 506 and the gate conductive material layer 504 are sequentially formed. The surface of the P-type well area 402 covered by the gate conductive material layer 504 is used to form the conductive channel. Subsequently, the sidewalls 505 are also formed on the sides of the gate conductive material layer 504.

Afterwards, the method further includes: forming sidewall 505 on the side of gate conductive material layer 504.

Step 6: N⁺ ion implantation is performed to form the first source/drain area 403 in the surface area of the first N-type deep diffusion area 502a and the second source/drain area 404 in the surface area of the second N-type deep diffusion area 502b.

Step 7: P⁺ ion implantation is performed to form substrate contact area 405 in the surface area of the P-type deep diffusion area 503.

The above detailed description of embodiments of the present application is provided for illustrative purposes only and should not be construed as limiting the protection scope. It should be understood by those skilled in the art that various modifications and improvements can be made without departing from the spirit and scope of the invention. Such modifications and improvements should also be considered to fall within scope of the invention as defined by the appended claims.

What is claimed is:

1. A high-voltage NMOSFET, comprising: a first active area having block shape, a second active area and a third active area each having strip shape and a fourth active area having annular shape, all formed in a P-type doped semiconductor substrate and surrounded by a field oxide layer, wherein
the first active area has opposite first side surface and second side surface as well as opposite third side surface and fourth side surface, wherein
the direction from the first side surface to the second side surface corresponds to the channel length direction, and direction from the third side surface to the fourth side surface corresponds to channel width direction, wherein
the second active area is located outside first side surface of the first active area, and the third active area is located outside second side surface of the second active area, wherein
the fourth active area is disposed to surround the peripheral sides of the first, second, and third active areas, wherein
a P-type well area is formed in the first active area, and a gate dielectric layer as well as a gate conductive material layer are sequentially formed on the top surface of the first active area, wherein surface of P-type well area covered by the gate conductive material layer is configured to form a conduction channel;
a first N-type deep diffusion area is formed in second active area, and an N⁺-doped first source/drain area is formed in surface area of first N-type deep diffusion area;
a second N-type deep diffusion area is formed in third active area, and a N⁺-doped second source/drain area is formed in surface area of the second N-type deep diffusion area;
a P-type deep diffusion area is formed in the fourth active area, and a P⁺-doped substrate contact area is formed in surface area of P-type deep diffusion area, wherein
P-type deep diffusion area is formed by diffusion of P-type impurities introduced through P-type ion implantation, wherein a P-type ion implantation area of the P-type deep diffusion area is larger than the fourth active area and extends into an adjacent field oxide layer, wherein the P-type ion implantation area comprises a first protruding portion located in an area between a third side surface of the first active area and a corresponding portion of the fourth active area, wherein the P-type ion implantation area comprises a second protruding portion located in the area between the fourth side surface of the first active area and the corresponding portion of the fourth active area, wherein
P-type impurities implanted by P-type ion implantation in the P-type deep diffusion area at the first protruding portion and the second protruding portion are incorporated into the field oxide layer to reduce segregation of P-type impurities from the third and fourth side surfaces of first active area into the field oxide layer, thereby increasing threshold voltage of the corner areas at the third and fourth side surfaces of the first active area.

2. The high-voltage NMOSFET according to claim 1, wherein the first N-type deep diffusion area a well as the second N-type deep diffusion area are both formed by the diffusion of N-type impurities introduced through N-type ion implantation, wherein
an N-type ion implantation area of the first N-type deep diffusion area is larger than the second active area and extends into an adjacent field oxide layer and into the first active area, and wherein
an N-type ion implantation area of the second N-type deep diffusion area is larger than the third active area and extends into an adjacent field oxide layer and into first active area.

3. The high-voltage NMOSFET according to claim 2, wherein a minimum distance between the first protruding portion and an adjacent N-type ion implantation area of the first N-type deep diffusion area is greater than or equal to a distance between an inner edge of a P-type ion implantation area of the P-type deep diffusion area (outside the first as well as second protruding portions) and an adjacent edge of the N-type ion implantation area of the first N-type deep diffusion area, and wherein
a minimum distance between the second protruding portion and an adjacent N-type ion implantation area of the second N-type deep diffusion area is greater than or equal to a distance between an inner edge of P-type ion implantation area of P-type deep diffusion area (outside the first and second protruding portions) and an adjacent edge of the N-type ion implantation area of the second N-type deep diffusion area.

4. The high-voltage NMOSFET according to claim 2, wherein the bottom surfaces of the first N-type deep diffusion area, the second N-type deep diffusion area, and the P-type deep diffusion area all extend below a bottom surface of the field oxide layer.

5. The high-voltage NMOSFET according to claim 1, wherein P-type impurities introduced by P-type ion implantation into the P-type deep diffusion area comprise boron, and wherein
the dopant impurities in the P-type well area comprise boron.

6. The high-voltage NMOSFET according to claim 1, wherein high-voltage P-well is formed in surface area of the semiconductor substrate, and the first active area, the second active area, the third active area as well as the fourth active area are all formed within the high-voltage P-well.

7. The high-voltage NMOSFET according to claim 6, wherein P-type well area is formed from the high-voltage P-well.

8. The high-voltage NMOSFET according to claim 1, wherein the semiconductor substrate comprises a silicon substrate.

9. A method for manufacturing a high-voltage NMOSFET, comprising:
Step 1: forming a field oxide layer in a P-type doped semiconductor substrate and forming a first active area in a block shape, a second active area and a third active area in a strip shape, and a fourth active area in an annular shape surrounded by the field oxide layer, wherein
the first active area has opposite first and second side surfaces and opposite third and fourth side surfaces, wherein
direction from the first side surface to the second side surface represents a channel length direction, and direction from the third side surface to the fourth side surface represents a channel width direction, wherein
the second active area is located outside first side surface of the first active area, the third active area is located outside second side surface of the second active area, and
the fourth active area is disposed to surround peripheral sides of the first active region, the second active region, and the third active region;
Step 2: forming a P-type well area in the first active area;
Step 3: performing the N-type ion implantation and diffusing the implanted N-type impurities to form a first N-type deep diffusion area in the second active area and a second N-type deep diffusion area in the third active area;
Step 4: performing P-type ion implantation and diffusing implanted P-type impurities to form the P-type deep diffusion area in the fourth active area, wherein
the P-type ion implantation area of the P-type deep diffusion area is larger than the fourth active area and extends into adjacent field oxide layer, wherein P-type ion implantation area comprises a first protruding portion located in area between the third side surface of the first active area and a corresponding portion of the fourth active area, and a second protruding portion is located in area between the fourth side surface of the first active area as well as a corresponding portion of the fourth active area, wherein
at the first and second protruding portions, P-type impurities introduced by P-type ion implantation are incorporated into the field oxide layer to reduce segregation of the P-type impurities from the third and fourth side surfaces of the first active area into the field oxide layer, thereby increasing threshold voltage in corner areas at the third and fourth side surfaces of the first active area;
Step 5: forming gate dielectric layer and gate conductive material layer sequentially on top surface of the first active area, wherein surface of the P-type well area covered by the gate conductive material layer is configured to form a conduction channel;
Step 6: performing N⁺ ion implantation to form the first source/drain area in surface area of the first N-type deep diffusion area and the second source/drain area in surface area of the second N-type deep diffusion area; and
Step 7: performing P⁺ ion implantation to form the substrate contact area in surface area of the P-type deep diffusion area.

10. The method for manufacturing a high-voltage NMOSFET according to claim 9, wherein N-type ion implantation area of first N-type deep diffusion area is larger than the second active area and extends into adjacent field oxide layer and into the first active area, and wherein
an N-type ion implantation area of the second N-type deep diffusion area is larger than the third active area and extends into adjacent field oxide layer and into the first active area.

11. The method for manufacturing a high-voltage NMOSFET according to claim 10, wherein a minimum distance between the first protruding portion as well as an adjacent N-type ion implantation area of first N-type deep diffusion area is greater than or equal to a distance between an inner edge of a P-type ion implantation area of the P-type deep diffusion area (outside the first as well as second protruding portions) and adjacent edge of the N-type ion implantation area of the first N-type deep diffusion area, and wherein
a minimum distance between the second protruding portion and adjacent N-type ion implantation area of the second N-type deep diffusion area is greater than or equal to the distance between an inner edge of P-type ion implantation area of the P-type deep diffusion area (outside the first and second protruding portions) and adjacent edge of the N-type ion implantation area of the second N-type deep diffusion area.

12. The method for manufacturing a high-voltage NMOSFET according to claim 10, wherein the bottom surface of the first N-type deep diffusion area, the second N-type deep diffusion area and the P-type deep diffusion area all extend below bottom surface of the field oxide layer.

13. The method for manufacturing a high-voltage NMOSFET according to claim 9, wherein P-type impurities introduced by P-type ion implantation into the P-type deep diffusion area comprise boron, and wherein
the dopant impurities in the P-type well area comprise boron.

14. The method for manufacturing a high-voltage NMOSFET according to claim 9, wherein a high-voltage P-well is formed in a surface area of the semiconductor substrate, and the first active area, the second active area, the third active area and the fourth active area are all formed within the high-voltage P-well.

15. The method for manufacturing a high-voltage NMOSFET according to claim 14, wherein the P-type well area is formed from the high-voltage P-well.

16. The method for manufacturing a high-voltage NMOSFET according to claim 9, wherein the semiconductor substrate comprises a silicon substrate.
